(19) United States
(12) Patent Application Publication
(10) Pub. No.: US 2026/0135351 A1
(43) Pub. Date: May 14, 2026

(54) A SEMICONDUCTOR LIGHT-EMITTING STRUCTURE AND A METHOD FOR MANUFACTURING THE SEMICONDUCTOR LIGHT-EMITTING STRUCTURE

(71) Applicants: SUZHOU EVERBRIGHT PHOTONICS CO., LTD., Suzhou (CN); EVERBRIGHT INSTITUTE OF SEMICONDUCTOR PHOTONICS CO., LTD., Suzhou (CN)

(72) Inventors: Jun Wang, Suzhou (CN); Yang Cheng, Suzhou (CN); Wu Zhao, Suzhou (CN); Fangyuan Sun, Suzhou (CN); Yuhang Zhang, Suzhou (CN); Dayong Min, Suzhou (CN)

(73) Assignees: SUZHOU EVERBRIGHT PHOTONICS CO., LTD., Suzhou (CN); EVERBRIGHT INSTITUTE OF SEMICONDUCTOR PHOTONICS CO., LTD., Suzhou (CN)

(21) Appl. No.: 19/148,706

(22) PCT Filed: Mar. 7, 2025
(86) PCT No.: PCT/CN2025/081358

§ 371 Date: Jul. 17, 2025

(30) Foreign Application Priority Data
Mar. 8, 2024 (CN) 202410263217.5

(51) Int. Cl. H01S 5/34; H01S 5/026; H01S 5/40

(52) U.S. Cl. CPC H01S 5/3401; H01S 5/026; H01S 5/4043

(57) ABSTRACT

A semiconductor light-emitting structure includes a semiconductor substrate layer, a first limiting layer, a first waveguide layer, an active layer, a second waveguide layer, and a second limiting layer stacked in sequence. The active layer comprises a first superlattice active layer and a second superlattice active layer stacked in sequence, and the second superlattice active layer is located on a side of the first superlattice active layer away from the first waveguide layer. The semiconductor light-emitting structure further includes an insertion layer disposed between the second superlattice active layer and the first superlattice active layer. A refractive index of the insertion layer is less than an effective refractive index of the first superlattice active layer and less than an effective refractive index of the second superlattice active layer.

### RELATED APPLICATIONS

The present application claims priority to Chinese Patent Application No. 202410263217.5, filed to the China National Intellectual Property Administration (CNIPA) on Mar. 8, 2024, and entitled “A SEMICONDUCTOR LIGHT-EMITTING STRUCTURE AND A METHOD FOR MANUFACTURING THE SEMICONDUCTOR LIGHT-EMITTING STRUCTURE”, the entire content of which is incorporated herein by reference.

### TECHNICAL FIELD

The present application relates to the technical field of semiconductors, and in particular relates to a semiconductor light-emitting structure and a method for manufacturing the semiconductor light-emitting structure.

### BACKGROUND

A semiconductor light-emitting structure is a structure that generates stimulated emission effect by using certain semiconductor material as a working substance, and a working principle thereof is that the particle number of non-equilibrium carriers is inverted by a certain excitation method to generate stimulated emission effect. Semiconductor light-emitting structures are widely used due to small volume and high electro-optical conversion efficiency.

Quantum cascade lasers are an important type of light-emitting structure, with the spectral range thereof covering the mid-infrared to far-infrared wavelength bands, can be used in a variety of aspects, such as trace gas detection and free-space optical communication, and have a broad market application prospect. A channel buried ridge structure is usually adopted in mid-infrared quantum cascade lasers, wherein the active region is etched into a single-ridge type, and, by using the secondary epitaxial growth technology, InP doped with Fe is filled on both sides of the ridge. InP doped with Fe has good properties of electrical insulation and thermal conductivity, which can ensure the heat dissipation capability and the optical confinement function of the device at the same time. After completing of a wafer process, the device will undergo cleavage and be coated, and a resonant cavity structure is constituted by evaporation-coating an anti-reflection film on the front cavity surface and evaporation-coating a reflection enhancement film on the back cavity surface.

Currently, semiconductor light-emitting structures in the prior art have a problem of beam quality degradation.

### SUMMARY OF THE INVENTION

Therefore, the technical problem to be solved by the present application is how to improve the beam quality of a semiconductor light-emitting structure, so as to provide a semiconductor light-emitting structure and a method for manufacturing the semiconductor light-emitting structure.

A semiconductor light-emitting structure is provided in the present application, and comprises: a semiconductor substrate layer, a first limiting layer, a first waveguide layer, an active layer, a second waveguide layer, and a second limiting layer stacked in sequence; wherein the active layer comprises a first superlattice active layer and a second superlattice active layer stacked in sequence, and the second superlattice active layer is located on a side of the first superlattice active layer away from the first waveguide layer; the semiconductor light-emitting structure further comprises: an insertion layer disposed between the second superlattice active layer and the first superlattice active layer, wherein a refractive index of the insertion layer is less than an effective refractive index of the first superlattice active layer and less than an effective refractive index of the second superlattice active layer.

Optionally, the semiconductor light-emitting structure further comprises: a first lattice matching layer disposed between the first superlattice active layer and the insertion layer, and a first transition layer disposed between the first lattice matching layer and the insertion layer, wherein the first lattice matching layer is in contact with the first superlattice active layer, a conduction band energy level of the first transition layer is higher than that of the first lattice matching layer and lower than that of the insertion layer; and/or, the semiconductor light-emitting structure further comprises: a second lattice matching layer disposed between the second superlattice active layer and the insertion layer, and a second transition layer disposed between the second lattice matching layer and the insertion layer, wherein the second lattice matching layer is in contact with the second superlattice active layer, a conduction band energy level of the second transition layer is higher than that of the second lattice matching layer and lower than that of the insertion layer.

Optionally, the first transition layer comprises a plurality of first sub-transition layers stacked in sequence; conduction band energy levels of the plurality of first sub-transition layers stacked in sequence increase layer-by-layer in a stacking arrangement direction from the first superlattice active layer to the insertion layer; or, the first transition layer is a single-layer structure, and the conduction band energy level of the first transition layer is constant in a thickness direction thereof.

Optionally, the second transition layer comprises a plurality of second sub-transition layers stacked in sequence; conduction band energy levels of the plurality of second sub-transition layers stacked in sequence increase layer-by-layer in a stacking arrangement direction from the second superlattice active layer to the insertion layer; or, the second transition layer is a single-layer structure, and the conduction band energy level of the second transition layer is constant in a thickness direction thereof.

Optionally, the semiconductor light-emitting structure further comprises: a third lattice matching layer disposed between the first superlattice active layer and the first waveguide layer, and a third transition layer disposed between the third lattice matching layer and the first waveguide layer, wherein the third lattice matching layer is in contact with the first superlattice active layer, and a conduction band energy level of the third transition layer is higher than that of the third lattice matching layer and lower than that of the first waveguide layer; and/or, the semiconductor light-emitting structure further comprises: a fourth lattice matching layer disposed between the second superlattice active layer and the second waveguide layer, and a fourth transition layer disposed between the fourth lattice matching layer and the second waveguide layer, wherein the fourth lattice matching layer is in contact with the second superlattice active layer, and a conduction band energy level of the fourth transition layer is higher than that of the fourth lattice matching layer and lower than that of the second waveguide layer.

Optionally, the third transition layer comprises a plurality of third sub-transition layers stacked in sequence; conduction band energy levels of the plurality of third sub-transition layers stacked in sequence decrease layer-by-layer in a stacking arrangement direction from the first waveguide layer to the first superlattice active layer; or, the third transition layer is a single-layer structure, and the conduction band energy level of the third transition layer is constant in a thickness direction thereof.

Optionally, the fourth transition layer comprises a plurality of fourth sub-transition layers stacked in sequence; conduction band energy levels of the plurality of fourth sub-transition layers stacked in sequence decrease layer-by-layer in a stacking arrangement direction from the second waveguide layer to the second superlattice active layer; or, the fourth transition layer is a single-layer structure, and the conduction band energy level of the fourth transition layer is constant in a thickness direction thereof.

Optionally, the insertion layer is an InP insertion layer with or without doped conductive ions, or the insertion layer is an InAlAs insertion layer with or without doped conductive ions, or the insertion layer is an InGaAlAs insertion layer with or without doped conductive ions.

Optionally, the thickness of the insertion layer is 0.6 μm to 1.2 μm.

Optionally, the first superlattice active layer comprises a plurality of first barrier layers and a plurality of first quantum well layers, the first barrier layers and the first quantum well layers are stacked in an alternating and spaced way with respect to each other, both a top layer and a bottom layer of the first superlattice active layer are one of the first barrier layers, and a conduction band energy level of each of the first quantum well layers is lower than that of each of the first barrier layers; the second superlattice active layer comprises a plurality of second barrier layers and a plurality of second quantum well layers, the second barrier layers and the second quantum well layers are stacked in an alternating and spaced way with respect to each other, both a top layer and a bottom layer of the second superlattice active layer are one of the second barrier layers, and a conduction band energy level of each of the second quantum well layers is lower than that of each of the second barrier layers; a conduction band energy level of the insertion layer is higher than that of each of the first quantum well layers and lower than that of each of the first barrier layers, and the conduction band energy level of the insertion layer is higher than that of each of the second quantum well layers and lower than that of each of the second barrier layers.

Optionally, a thickness of the first superlattice active layer is 0.8 μm to 1.0 μm; and, a thickness of the second superlattice active layer is 0.8 μm to 1.0 μm.

Optionally, a width of the active layer is 8 μm to 10 μm.

Optionally, the first superlattice active layer comprises a first sub-superlattice region and a second sub-superlattice region, wherein the second sub-superlattice region is disposed on a side of the first sub-superlattice region away from the first waveguide layer, and a doping concentration of conductive ions in the second sub-superlattice region is greater than that of conductive ions in the first sub-superlattice region; and/or, the second superlattice active layer comprises a third sub-superlattice region and a fourth sub-superlattice region, wherein the fourth sub-superlattice region is disposed on a side of the third sub-superlattice region away from the insertion layer, and a doping concentration of conductive ions in the third sub-superlattice region is greater than that of conductive ions in the fourth sub-superlattice region.

Optionally, the doping concentration of conductive ions in the third sub-superlattice region is 20% to 50% higher than that of conductive ions in the fourth sub-superlattice region; and/or, the doping concentration of conductive ions in the second sub-superlattice region is 20% to 50% higher than that of conductive ions in the first sub-superlattice region.

Optionally, an middle surface between a surface on a side of the first superlattice active layer away from the second superlattice active layer to a surface on a side of the second superlattice active layer away from the first superlattice active layer is located in the insertion layer; a distance from the middle surface to the surface on the side of the first superlattice active layer away from the second superlattice active layer is equal to a distance from the middle surface to the surface on the side of the second superlattice active layer away from the first superlattice active layer.

A method for manufacturing the semiconductor light-emitting structure is provided in the present application, and comprises: providing a semiconductor substrate layer; forming a first limiting layer, a first waveguide layer, an active layer, a second waveguide layer, and a second limiting layer in sequence on the semiconductor substrate layer; wherein the step of forming the active layer comprises: stacking a first superlattice active layer and a second superlattice active layer in sequence; the method for manufacturing the semiconductor light-emitting structure further comprises: before forming the second superlattice active layer, forming an insertion layer on a side of the first superlattice active layer away from the first waveguide layer; wherein a refractive index of the insertion layer is less than an effective refractive index of the first superlattice active layer and less than an effective refractive index of the second superlattice active layer.

Optionally, the method further comprises: before forming the insertion layer, forming a first lattice matching layer on a side of the first superlattice active layer away from the first waveguide layer; and forming a first transition layer on a side of the first lattice matching layer away from the first waveguide layer; wherein a conduction band energy level of the first transition layer is higher than that of the first lattice matching layer and lower than that of the insertion layer; and the step of forming the insertion layer comprises: forming the insertion layer on a side of the first transition layer away from the first waveguide layer; and/or, the method further comprises: before forming the second superlattice active layer, forming a second transition layer on a side of the insertion layer away from the first superlattice active layer; forming a second lattice matching layer on a side of the second transition layer away from the first superlattice active layer; wherein a conduction band energy level of the second transition layer is higher than that of the second lattice matching layer and lower than that of the insertion layer; and the step of forming the second superlattice active layer comprises: forming the second superlattice active layer on a side of the second lattice matching layer away from the first superlattice active layer.

Optionally, the step of forming the first transition layer on a side of the first lattice matching layer away from the first waveguide layer comprises forming a plurality of first sub-transition layers stacked in sequence; wherein conduction band energy levels of the plurality of first sub-transition layers stacked in sequence increase layer-by-layer in a stacking arrangement direction from the first superlattice active layer to the insertion layer.

Optionally, the step of forming the second transition layer on a side of the insertion layer away from the first superlattice active layer comprises: forming a plurality of second sub-transition layers stacked in sequence; wherein conduction band energy levels of the plurality of second sub-transition layers stacked in sequence increase layer-by-layer in a stacking arrangement direction from the second superlattice active layer to the insertion layer.

Optionally, the method further comprises: before forming the first superlattice active layer, forming a third transition layer on a side of the first waveguide layer away from the first limiting layer; and forming a third lattice matching layer on a side of the third transition layer away from the first limiting layer; wherein a conduction band energy level of the third transition layer is higher than that of the third lattice matching layer and lower than that of the first waveguide layer; and the step of forming the first superlattice active layer comprises: forming the first superlattice active layer on a side of the third lattice matching layer away from the first limiting layer; and/or, the method further comprises: before forming the second waveguide layer, forming a fourth lattice matching layer on a side of the second superlattice active layer away from the first superlattice active layer; and forming a fourth transition layer on a side of the fourth lattice matching layer away from the first superlattice active layer, wherein a conduction band energy level of the fourth transition layer is higher than that of the fourth lattice matching layer and lower than that of the second waveguide layer; and the step of forming the second waveguide layer comprises: forming the second waveguide layer on a side of the fourth transition layer away from the first superlattice active layer.

Optionally, the step of forming the third transition layer on a side of the first waveguide layer away from the first limiting layer comprises: forming a plurality of third sub-transition layers stacked in sequence; wherein conduction band energy levels of the plurality of third sub-transition layers stacked in sequence decrease layer-by-layer in a stacking arrangement direction from the first waveguide layer to the first superlattice active layer.

Optionally, the step of forming the fourth transition layer on a side of the fourth lattice matching layer away from the first superlattice active layer comprises: forming a plurality of fourth sub-transition layers stacked in sequence; wherein conduction band energy levels of the plurality of fourth sub-transition layers stacked in sequence decrease layer-by-layer in a stacking arrangement direction from the second waveguide layer to the second superlattice active layer.

Optionally, the step of forming the first superlattice active layer comprises: forming a first sub-superlattice region and a second sub-superlattice region stacked in sequence, wherein the second sub-superlattice region is disposed on a side of the first sub-superlattice region away from the first waveguide layer, and a doping concentration of conductive ions in the second sub-superlattice region is greater than that of conductive ions in the first sub-superlattice region; and/or, the step of forming the second superlattice active layer comprises: forming a third sub-superlattice region and a fourth sub-superlattice region stacked in sequence, wherein the fourth sub-superlattice region is disposed on a side of the third sub-superlattice region away from the insertion layer, and a doping concentration of conductive ions in the third sub-superlattice region is greater than that of conductive ions in the fourth sub-superlattice region.

The technical solution of the present application has the following beneficial effects:

The technical solution of the present application provides a semiconductor light-emitting structure in which the insertion layer is disposed such that a single active layer is divided into a first superlattice active layer and a second superlattice active layer spaced from each other. The insertion layer does not contribute to the gain value. Since a refractive index of the insertion layer is less than an effective refractive index of the first superlattice active layer and less than an effective refractive index of the second superlattice active layer, the insertion layer is used to reduce the optical confinement factor of the transverse modes. Specifically, the degree to which the insertion layer reduces the light confinement factor of the high-order modes is greater than the degree to which it reduces the light confinement factor of the basic mode, and the insertion layer makes the difference between the light confinement factor of the basic mode and the light confinement factor of the higher-order modes larger, thereby making the difference between the threshold gain of the higher-order modes and the threshold gain of the basic mode larger, so that the higher-order modes are effectively suppressed, thereby making the semiconductor light-emitting structure work stably, and improving the beam quality of the semiconductor light-emitting structure.

### BRIEF DESCRIPTION OF THE DRAWINGS

In order to more clearly illustrate the technical solutions in the specific embodiments of the present application or in the prior art, the drawings need to be used in the description of the specific embodiments or the prior art will be briefly introduced, and apparently, the drawings described below only represent some of the embodiments of the present application, and for a person with ordinary skill in the art, other drawings can be obtained according to these drawings, without expenditure of creative labor.

FIG. 1 is a schematic diagram of a semiconductor light-emitting structure in the related art;

FIG. 2 is a schematic diagram of a semiconductor light-emitting structure in an embodiment of the present application;

FIG. 3 is a schematic diagram of a semiconductor light-emitting structure in another embodiment of the present application.

### DETAILED DESCRIPTION

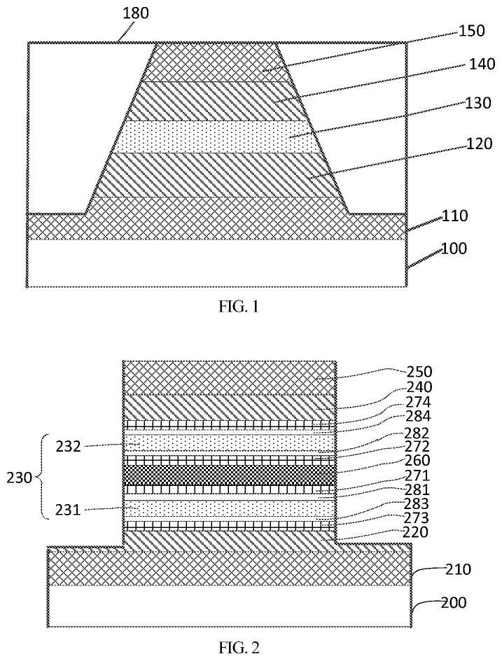

A semiconductor light-emitting structure, referring to FIG. 1, comprises: a substrate layer 100; a lower limiting layer 110, a lower waveguide layer 120, an active layer 130, an upper waveguide layer 140, and an upper limiting layer 150 located on the substrate layer 100; and an insulating epitaxial layer 180 located on the sidewalls of the lower waveguide layer 120, the active layer 130, the upper waveguide layer 140, and the upper limiting layer 150.

The above-mentioned semiconductor light-emitting structure has a problem of beam quality degradation. It has been found by research that this is due to the fact that light field modes present in the active layer 130 have higher-order modes such as a first-order mode and a second-order mode in addition to a basic mode. On a light-emitting surface of the semiconductor light-emitting structure, the light field of the basic mode has only one facula; on the light-emitting surface of the semiconductor light-emitting structure, the light field of the first-order mode has two small faculae, and the two small faculae are distributed in a width direction of the semiconductor light-emitting structure; and on the light-emitting surface of the semiconductor light-emitting structure, the light field of the second-order mode has three small faculae, and the three small faculae are distributed in the width direction of the semiconductor light-emitting structure. The lower waveguide layer 120, the active layer 130, the upper waveguide layer 140, and the upper limiting layer 150 form a ridge structure, and the ridge structure reduces the optical absorption and scattering on a sidewall of the active layer 130, wherein the basic mode, the first-order mode, and the second-order mode have similar optical loss values, so that the fundamental mode, the first-order mode, and the second-order mode coexist in the active layer 130. When the semiconductor light-emitting structure operates, three lateral light field modes can appear simultaneously, accompanied by a certain phenomenon of light field mode switching, which causes the light wave field of the semiconductor light-emitting structure to have a state of mode instability, and parameters such as the far-field divergence angle and the excitation wavelength would gradually drift with an increase in electrical current, ultimately leading to a degradation of the light beam quality of the semiconductor light-emitting structure.

In order to suppress the higher-order modes, the simplest way is to reduce a ridge width of the active layer 130. Taking the active layer 130 of a medium-wave 4.6 μm device as an example, when the ridge width of the active layer 130 is reduced to below 7 μm, theoretically, the optical confinement factor of the higher-order modes will be significantly reduced as compared to that of the basic transverse mode, thereby effectively suppressing the appearance of the higher-order modes.

However, there are many limitations in suppressing the higher-order modes by reducing the ridge width of the active layer 130: (1) after the ridge width of the active layer 130 is reduced, a gain volume of the active layer 130 is also reduced, causing a decrease in the light output power; (2) when the device is operating, there is a large number of carriers injected into the active layer 130, causing a change in the refractive index thereof; and at the same time, the temperature of the active layer 130 will increase dramatically during an operating process, which also causes a change in the refractive index of the active layer 130. The two effects ultimately lead to a change in the light confinement effect of the active layer 130, which weakens the suppression of the higher-order modes, and as a result, the higher-order modes reappear, causing the beam quality to degrade.

On this basis, the present application provides a semiconductor light-emitting structure and a method for manufacturing the semiconductor light-emitting structure to prevent beam quality degradation.

The technical solutions of the present application will be described clearly and completely below with reference to the drawings, and apparently, the described embodiments only represent a part of the embodiments of the present application, not all of them. Based on the embodiments described in the present application, all other embodiments obtainable by a person with ordinary skill in the art without expenditure of creative labor fall within the scope of protection of the present application.

In the description of the present application, it needs to be clarified that the orientation or positional relationships indicated by terms such as ‘center’, ‘upper’, “lower”, ‘left’, ‘right’, ‘vertical’, ‘horizontal’, “inside”, ‘outside’, etc. are based on those shown in the drawings, and are intended only for the purpose of facilitating the description of the present application and simplifying the description, and are not intended to indicate or imply that the device or element referred to must be of a particular orientation, or must be constructed and operated with a particular orientation, and therefore are not to be understood as limitations to the present application. Furthermore, terms such as ‘first’, “second”, and ‘third’ are used for descriptive purposes only and are not to be understood as indicating or implying relative importance.

Furthermore, the technical features involved in different embodiments of the present application described below may be combined with each other as long as they do not conflict with each other.

### Embodiment 1

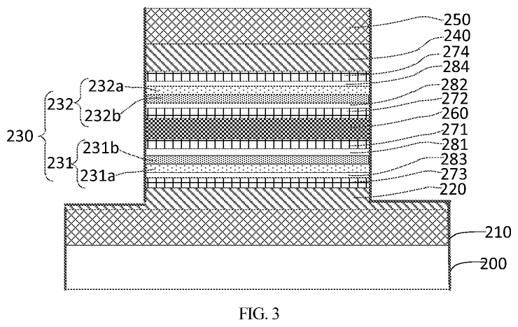

An embodiment of the present application provides a semiconductor light-emitting structure, referring to FIG. 2, it comprises: a semiconductor substrate layer 200, a first limiting layer 210, a first waveguide layer 220, an active layer 230, a second waveguide layer 240, and a second limiting layer 250 stacked in sequence; wherein the active layer 230 comprises a first superlattice active layer 231 and a second superlattice active layer 232 stacked in sequence, the second superlattice active layer 232 is located on a side of the first superlattice active layer 231 away from the first waveguide layer 220. The semiconductor light-emitting structure further comprises: an insertion layer 260 disposed between the second superlattice active layer 232 and the first superlattice active layer 231, wherein a refractive index of the insertion layer 260 is less than an effective refractive index of the first superlattice active layer 231 and less than an effective refractive index of the second superlattice active layer 232.

In the present embodiment, the insertion layer 260 is disposed such that a single active layer 230 is divided into a first superlattice active layer 231 and a second superlattice active layer 232 spaced from each other. The insertion layer 260 does not contribute to the gain value. Since a refractive index of the insertion layer 260 is less than an effective refractive index of the first superlattice active layer 231 and less than an effective refractive index of the second superlattice active layer 232, the insertion layer 260 is used to reduce the optical confinement factor of the transverse modes. Specifically, the degree to which the insertion layer 260 reduces the light confinement factor of the high-order modes is greater than the degree to which it reduces the light confinement factor of the basic mode, and the insertion layer 260 makes the difference between the light limiting factor of the basic mode and the light limiting factor of the higher-order modes larger, thereby making the difference between the threshold gain of the higher-order modes and the threshold gain of the basic mode larger, so that the higher-order modes are effectively suppressed, thereby making the semiconductor light-emitting structure work stably, and improving the beam quality of the semiconductor light-emitting structure.

An order of each of the higher-order modes is larger than that of the basic mode. The higher-order modes include a first-order mode, a second-order mode, and those modes having a higher order than that of the second-order mode.

The effective refractive index of the first superlattice active layer 231 refers to an average refractive index of the first superlattice active layer 231 as a whole. The effective refractive index of the second superlattice active layer 232 refers to an average refractive index of the second superlattice active layer 232 as a whole.

In the present embodiment, taking the situation that the semiconductor light-emitting structure is a side-emitting semiconductor laser as an example, such as a quantum cascade side-emitting semiconductor laser, which comprises a mid-infrared quantum cascade side-emitting semiconductor laser.

In the present embodiment, the semiconductor substrate layer 200 is an InP substrate layer. It is noted that, in other examples, the semiconductor substrate layer 200 may also be made of other materials.

In an example, the material of the first limiting layer 210 is InP with doped conductive ions. Based on characteristics required for a mid-infrared quantum cascade side-emitting semiconductor laser, the first limiting layer 210 can only be made of InP that is doped with conductive ions.

In an example, a thickness of the first limiting layer 210 is from 2 μm to 4 μm, such as 2 μm.

In an example, the doping concentration of conductive ions in the first limiting layer 210 is 0.5×10¹⁷ atom/cm³˜5×10¹⁷ atom/cm³, for example, 2×10¹⁷ atom/cm³.

In an example, the material of the first waveguide layer 220 is InP with doped conductive ions, and the doping concentration of conductive ions in the first waveguide layer 220 is less than that of conductive ions in the first limiting layer 210.

In an example, the doping concentration of conductive ions in the first waveguide layer 220 is 1.0×10¹⁶ atom/cm³˜5.0×10¹⁶ atom/cm³, such as 2×10¹⁶ atom/cm³.

In an example, a thickness of the first waveguide layer 220 is 1 μm˜3 μm, such as 2 μm.

In an example, the material of the second limiting layer 250 is InP with doped conductive ions.

In an example, a thickness of the second limiting layer 250 is 1 μm˜3 μm, such as 2 μm.

In an example, the material of the second waveguide layer 240 is InP with doped conductive ions, and the doping concentration of conductive ions in the second waveguide layer 240 is less than that of conductive ions in the second limiting layer 250.

In an example, the doping concentration of conductive ions in the second waveguide layer 240 is 1.0×10¹⁶ atom/cm³˜5.0×10¹⁶ atom/cm³, such as 2×10¹⁶ atom/cm³.

In an example, a thickness of the second waveguide layer 240 is 1 μm to 3 μm, for example 2 μm.

Conductive types of the conductive ions in the first waveguide layer 220, the conductive ions in the first limiting layer 210, the conductive ions in the second waveguide layer 240 and the conductive ions in the second limiting layer 250 are consistent. For example, conductive types of the conductive ions in the first waveguide layer 220, the conductive ions in the first limiting layer 210, the conductive ions in the second waveguide layer 240, and the conductive ions in the second limiting layer 250 are n-type. The conductive ions of n-type comprise Si ions.

The first superlattice active layer 231 is a superlattice structure. The first superlattice active layer 231 comprises a plurality of first barrier layers and a plurality of first quantum well layers, the first barrier layers and the first quantum well layers are stacked in an alternating and spaced way with respect to each other, both a top layer and a bottom layer of the first superlattice active layer 231 are one of the first barrier layers. A band gap width of each of the first quantum well layers is less than that of each of the first barrier layers. A conduction band energy level of each of the first quantum well layers is lower than that of each of the first barrier layers.

The second superlattice active layer 232 is a superlattice structure. The second superlattice active layer 232 includes a plurality of second barrier layers and a plurality of second quantum well layers, the second barrier layers and the second quantum well layers are stacked in alternating and spaced way with respect to each other, both a top layer and a bottom layer of the second superlattice active layer 232 are one of the second barrier layers. A band gap width of each of the second quantum well layers is less than that of each of the second barrier layers. A conduction band energy level of each of the second quantum well layers is lower than that of each of the second barrier layers.

In an example, the material of the first quantum well layers and the second quantum well layers comprises InₓGa₍₁₋ₓ₎As, and the material of the first barrier layers and the second barrier layers comprises In_{y}Al_{(1-y)}As.

The first superlattice active layer 231 is with or without doped conductive ions. The second superlattice active layer 232 is with or without doped conductive ions. When the first superlattice active layer 231 is doped with conductive ions, the conductive type of conductive ions in the first superlattice active layer 231 is the same as the conductive type of conductive ions in the first limiting layer 210, the first waveguide layer 220, the second waveguide layer 240 and the second limiting layer 250. When the second superlattice active layer 232 is doped with conductive ions, the conductive type of conductive ions in the second superlattice active layer 232 is the same as the conductive type of conductive ions in the first limiting layer 210, the first waveguide layer 220, the second waveguide layer 240, and the second limiting layer 250. For example, the conductive type of conductive ions in the first superlattice active layer 231 is n-type, and the conductive type of conductive ions in the second superlattice active layer 232 is n-type. Specifically, in an example, the conductive ions in the first superlattice active layer 231 and the second superlattice active layer 232 are, for example, Si ions.

In an example, the doping concentration of conductive ions in the first superlattice active layer 231 is constant in the thickness direction. The doping concentration of conductive ions in the second superlattice active layer 232 is constant in the thickness direction.

In an example, a thickness of the first superlattice active layer 231 is 0.8 μm to 1.0 μm, and a thickness of the second superlattice active layer 232 is 0.8 μm to 1.0 μm.

The thickness of each of the first barrier layers is small, so that each of the first barrier layers has a tunneling effect. The thickness of each of the second barrier layers is smaller so that each of the second barrier layers has a tunnelling effect. In an example, the thickness of each of the first barrier layers is 1 nm˜3 nm. In an example, the thickness of each of the second barrier layers is 1 nm˜3 nm.

In an example, a width of the active layer 230 is 8 μm˜10 μm. A width of the active layer 230 is relatively wide, so as to improve the light output power.

In an example, the insertion layer 260 is an InP insertion layer with or without doped conductive ions, or the insertion layer 260 is an InAlAs insertion layer with or without doped conductive ions, or the insertion layer 260 is an InGaAlAs insertion layer with or without doped conductive ions.

In an example, the conductive type of conductive ions in the insertion layer 260 is the same as the conductive type of conductive ions in the first limiting layer 210, the first waveguide layer 220, the second waveguide layer 240 and the second limiting layer 250. In an example, the conductive ions in the insertion layer 260 are n-type, for example the conductive ions thereof are Si ions.

In an example, the doping concentration of conductive ions in the insertion layer 260 is 1.0×10¹⁶ atom/cm³ to 5.0×10¹⁶ atom/cm³, such as 2×10¹⁶ atom/cm³.

In an example, a band gap width of the insertion layer 260 is greater than that of each of the second quantum well layers and less than that of each of the second barrier layers, and the bandgap width of the insertion layer 260 is greater than that of each of the first quantum well layers and less than that of each of the first barrier layers. A conduction band energy level of the insertion layer 260 is higher than that of each of the first quantum well layers and lower than that of each of the first barrier layers. The conduction band energy level of the insertion layer 260 is higher than that of each of the second quantum well layers and lower than each of that of the second barrier layers.

In an example, a thickness of the insertion layer 260 is 0.6 μm and 1.2 μm.

In an example, a relationship between the thickness of the insertion layer 260 and a light-emitting wavelength of the semiconductor light-emitting structure is as follows: the thickness of the insertion layer 260 is 15% to 50% of the light-emitting wavelength.

A relationship between the thickness of the insertion layer 260 and the thickness of the first superlattice active layer 231 is as follows: the thickness of the insertion layer 260 is 50% to 150% of the thickness of the first superlattice active layer 231. A relationship between the thickness of the insertion layer 260 and the thickness of the second superlattice active layer 232 is as follows: the thickness of the insertion layer 260 is 50˜150% of the thickness of the second superlattice active layer 232. The thickness of the insertion layer 260 is set such that the insertion layer 260 contributes to causing loss of higher order modes.

A middle surface between a surface on a side of the first superlattice active layer 231 away from the second superlattice active layer 232 to a surface on a side of the second superlattice active layer 232 away from the first superlattice active layer 231 is located in the insertion layer 260. A distance from the middle surface to the surface on the side of the first superlattice active layer 231 away from the second superlattice active layer 232 is equal to a distance from the middle surface to the surface on the side of the second superlattice active layer 232 away from the first superlattice active layer 231.

In an example, the semiconductor light-emitting structure further comprises: a first lattice matching layer 281 disposed between the first superlattice active layer 231 and the insertion layer 260, and a first transition layer 271 disposed between the first lattice matching layer 281 and the insertion layer 260, wherein the first lattice matching layer 281 is in contact with the first superlattice active layer 231, a conduction band energy level of the first transition layer 271 is higher than that of the first lattice matching layer 281 and lower than that of the insertion layer 260; and, the semiconductor light emitting structure further comprises: a second lattice matching layer 282 disposed between the second superlattice active layer 232 and the insertion layer 260, and a second transition layer 272 disposed between the second lattice matching layer 282 and the insertion layer 260, wherein the second lattice matching layer 282 is in contact with the second superlattice active layer 232, a conduction band energy level of the second transition layer 272 is higher than that of the second lattice matching layer 282 and lower than that of the insertion layer 260.

A band gap width of the first transition layer 271 is greater than that of the first lattice matching layer 281 and less than that of the insertion layer 260. A band gap width of the second transition layer 272 is greater than that of the second lattice matching layer 282 and less than that of the insertion layer 260.

In another examples, the semiconductor light-emitting structure further comprises: a first lattice matching layer and a first transition layer; or, the semiconductor light emitting structure further comprises: a second lattice matching layer and a second transition layer.

In other examples, the first lattice matching layer, the first transition layer, the second lattice matching layer, and the second transition layer may not be provided.

In other examples, the first lattice matching layer and the second lattice matching layer are provided without providing the first transition layer and the second transition layer. In other examples, only one of the first lattice matching layer and the second lattice matching layer is provided. In other examples, none of the first lattice matching layer and the second lattice matching layer is provided. In other examples, only one of the first transition layer and the second transition layer is provided. In other examples, none of the first transition layer and the second transition layer is provided.

A band gap width of the first lattice matching layer 281 is greater than that of each of the first quantum well layers and less than that of each of the first barrier layers. A conduction band energy level of the first lattice matching layer 281 is higher than that of each of the first quantum well layers and lower than that of each of the first barrier layers. A crystalline lattice of the first lattice matching layer 281 matches a crystalline lattice of the semiconductor substrate layer 200. A band gap width of the second lattice matching layer 282 is greater than that of each of the second quantum well layers and less than each of that of the second barrier layers. A conduction band energy level of the second lattice matching layer 282 is higher than that of each of the second quantum well layers and lower than that of each of the second barrier layers. A crystalline lattice of the second lattice matching layer 282 matches the crystalline lattice of the semiconductor substrate layer 200.

The setting of the first lattice matching layer 281 can prevent the introduction of epitaxial defects caused by change of the material systems of the first barrier layers and the insertion layer 260, and reduce a defect density in the insertion layer 260. The setting of the second lattice matching layer 282 can prevent the introduction of epitaxial defects caused by change of the material systems of the second barrier layers and the insertion layer 260, and reduce a defect density in the second barrier layers.

In an example, the material of the first lattice matching layer 281 comprises Inₓ₁Ga₁₋ₓ₁As, the material of the second lattice matching layer 282 comprises Inₓ₁Ga₁₋ₓ₁As; and/or, the material of the first transition layer 271 comprises In_{1-y1}Ga_{y1}As_{1-z1}P_{z1} or In_{1-y2-z2}Ga_{y2}Al_{z2}As, and the material of the second transition layer 272 comprises In_{1-y1}Ga_{y1}As_{1-z1}P_{z1} or In_{1-y2-z2}Ga_{y2}Al_{z2}As.

In an example, the first transition layer 271 is with or without doped conductive ions. The second transition layer 272 is with or without doped conductive ions.

In an example, a doping concentration of conductive ions in the first transition layer 271 is 1.0×10¹⁶ atom/cm³˜5.0×10¹⁶ atom/cm³, such as 2×10¹⁶ atom/cm³. A doping concentration of conductive ions in the second transition layer 272 is 1.0×10¹⁶ atom/cm³˜5.0×10¹⁶atom/cm³, such as 2×10¹⁶ atom/cm³.

In an example, the first lattice matching layer 281 is doped with conductive ions. The second lattice matching layer 282 is doped with conductive ions. The conductive ions in the first lattice matching layer 281 and the second lattice matching layer 282 are the same as described in the above descriptions of conductive ions.

In an example, a thickness of the first lattice matching layer 281 is 10 nm to 40 nm, such as 20 nm; a thickness of the second lattice matching layer 282 is 10 nm to 40 nm, such as 20 nm; and/or, a thickness of the first transition layer 271 is 0.05 μm to 0.2 μm, and a thickness of the second transition layer 272 is 0.05 μm to 0.2 μm.

In an example, the first transition layer 271 comprises a plurality of first sub-transition layers stacked in sequence; conduction band energy levels of the plurality of first sub-transition layers stacked in sequence increase layer-by-layer in a stacking arrangement direction from the first superlattice active layer 231 to the insertion layer 260. Advantages thereof include: achieving gradual change of energy bands, reducing interface electrical resistance, decreasing the operating voltage of the semiconductor light-emitting structure, and suppressing thermal inversion and mode hopping.

In a specific example, the number of layers of the plurality of first sub-transition layers in the first transition layer 271 is three, and conduction band energy levels of the three first sub-transition layer increase layer-by-layer in a stacking arrangement from the first superlattice active layer 231 to the insertion layer 260. In other examples, there is no limitation on the number of layers of the first sub-transition layer.

In other examples, the first transition layer 271 is a single-layer structure, and the conduction band energy level of the first transition layer 271 is constant in the thickness direction thereof.

In an example, the second transition layer 272 comprises a plurality of second sub-transition layers stacked in sequence; conduction band energy levels of the plurality of second sub-transition layers stacked in sequence increase layer-by-layer in a stacking arrangement direction from the second superlattice active layer 232 to the insertion layer 260. Advantages thereof include: achieving gradual change of energy bands, reducing interface electrical resistance, decreasing the operating voltage of the semiconductor light-emitting structure, and suppressing thermal inversion and mode hopping.

In a specific example, the number of layers of the plurality of second sub-transition layers in the second transition layer 272 is three, and conduction band energy levels of the three second sub-transition layers increase layer-by-layer in a stacking arrangement direction from the second superlattice active layer 232 to the insertion layer 260. In other examples, there is no limitation on the number of layers of the second sub-transition layer.

In other examples, the second transition layer 272 is a single-layer structure, and the conduction band energy level of the second transition layer 272 is constant in the thickness direction thereof.

The function of the first transition layer 271 includes: reducing interfacial scattering of majority carriers, and enabling the majority carriers to be transported between the first superlattice active layer 231 and the second superlattice active layer 232. The function of the second transition layer 272 includes: reducing the interfacial scattering of majority carriers, enabling the majority carriers to be transported between the first superlattice active layer 231 and the second superlattice active layer 232.

In an example, the semiconductor light-emitting structure further comprises: a third lattice matching layer 283 disposed between the first superlattice active layer 231 and the first waveguide layer 220, and a third transition layer 273 disposed between the third lattice matching layer 283 and the first waveguide layer 220, wherein the third lattice matching layer 283 is in contact with the first superlattice active layer 231, and a conduction band energy level of the third transition layer 273 is higher than that of the third lattice matching layer 283 and lower than that of the first waveguide layer 220; and, the semiconductor light-emitting structure further comprises: a fourth lattice matching layer 284 disposed between the second superlattice active layer 232 and the second waveguide layer 240, and a fourth transition layer 274 disposed between the fourth lattice matching layer 284 and the second waveguide layer 240, wherein the fourth lattice matching layer 284 is in contact with the second superlattice active layer 232, and a conduction band energy level of the fourth transition layer 274 is higher than that of the fourth lattice matching layer 284 and lower than that of the second waveguide layer 240.

A band gap width of the third transition layer 273 is greater than that of the third lattice matching layer 283 and less than that of the first waveguide layer 220. A band gap width of the fourth transition layer 274 is greater than that of the fourth lattice matching layer 284 and less than that of the second waveguide layer 240.

In other examples, the semiconductor light emitting structure further comprises: a third lattice matching layer and a third transition layer; or, the semiconductor light emitting structure further comprises: a fourth lattice matching layer and a fourth transition layer.

In other examples, the third lattice matching layer, the third transition layer, the fourth lattice matching layer, and the fourth transition layer may not be provided.

In other examples, the third lattice matching layer and the fourth lattice matching layer are provided without providing the third transition layer and the fourth transition layer. In other examples, only one of the third lattice matching layer and the fourth lattice matching layer is provided. In other examples, none of the third lattice matching layer and the fourth lattice matching layer is provided. In other examples, only one of the third transition layer and the fourth transition layer is provided. In other examples, none of the third transition layer and the fourth transition layer is provided.

A band gap width of the third lattice matching layer 283 is greater than that of each of the first quantum well layers and less than that of each of the first barrier layers. A conduction band energy level of the third lattice matching layer 283 is higher than that of each of the first quantum well layers and lower than that of each of the first barrier layers. A crystalline lattice of the third lattice matching layer 283 matches a crystalline lattice of the semiconductor substrate layer 200. A band gap width of the fourth lattice matching layer 284 is greater than that of each of the second quantum well layers and less than that of each of the second barrier layers. A conduction band energy level of the fourth lattice matching layer 284 is higher than that of each of the second quantum well layers and lower than that of each of the second barrier layers. A crystalline lattice of the fourth lattice matching layer 284 matches the crystalline lattice of the semiconductor substrate layer 200.

The setting of the third lattice matching layer 283 can prevent the introduction of epitaxial defects caused by change of the material systems of the first barrier layers and the first waveguide layer 220, and reduce a defect density in the first barrier layer. The setting of the fourth lattice matching layer 284 can prevent the introduction of epitaxial defects caused by change of the material systems of the second barrier layer and the second waveguide layer 240, and reduce a defect density in the second waveguide layer 240.

In an example, the material of the third lattice matching layer 283 comprises Inₓ₁Ga₁₋ₓ₁As, and the material of the fourth lattice matching layer 284 comprises Inₓ₁Ga₁₋ₓ₁As; and/or, the material of the third transition layer 273 comprises In_{1-y3}Ga_{y3}As_{1-z3}P_{z3} or In_{1-y4-z4}Ga_{y4}Al_{z4}As; the material of the fourth transition layer 274 comprises In_{1-y3}Ga_{y3}As_{1-z3}P_{z3} or In_{1-y4-z4}Ga_{y4}Al_{z4}As.

In an example, the third transition layer 273 is with or without doped conductive ions. The fourth transition layer 274 is with or without doped conductive ions.

In an example, a doping concentration of conductive ions in the third transition layer 273 is 1.0×10¹⁶ atom/cm³˜5.0×10¹⁶ atom/cm³, such as 2×10¹⁶ atom/cm³. A doping concentration of conductive ions in the fourth transition layer 274 is 1.0×10¹⁶ atom/cm³˜5.0×10¹⁶atom/cm³, such as 2×10¹⁶ atom/cm³.

In an example, the third lattice matching layer 283 is doped with conductive ions. The fourth lattice matching layer 284 is doped with conductive ions. The conductive ions in the third lattice matching layer 283 and the fourth lattice matching layer 284 are the same as described in the above descriptions of conductive ions.

In an example, a thickness of the third lattice matching layer 283 is 10 nm to 40 nm, such as 20 nm; a thickness of the fourth lattice matching layer 284 is 10 nm to 40 nm, such as 20 nm; and/or, a thickness of the third transition layer 273 is 0.05 μm to 0.2 μm, and a thickness of the fourth transition layer 274 is 0.05 μm to 0.2 μm.

In an example, the third transition layer 273 comprises a plurality of third sub-transition layers stacked in sequence; conduction band energy levels of the plurality of third sub-transition layers stacked in sequence decrease layer-by-layer in a stacking arrangement direction from the first waveguide layer 220 to the first superlattice active layer 231. Advantages thereof include: achieving gradual change of energy bands, reducing interface electrical resistance, decreasing the operating voltage of the semiconductor light-emitting structure, and suppressing thermal inversion and mode hopping.

In a specific example, the number of layers of the plurality of third sub-transition layers in the third transition layer 273 is three, and conduction band energy levels of the three third sub-transition layers decrease layer-by-layer in a stacking arrangement direction from the first waveguide layer 220 to the first superlattice active layer 231. In other examples, there is no limitation on the number of layers of the third sub-transition layer.

In other examples, the third transition layer 273 is a single-layer structure, and the conduction band energy level of the third transition layer 273 is constant in the thickness direction thereof.

In an example, the fourth transition layer 274 comprises a plurality of fourth sub-transition layers stacked in sequence; conduction band energy levels of the plurality of fourth sub-transition layers stacked in sequence decrease layer-by-layer in a stacking arrangement direction from the second waveguide layer 240 to the second superlattice active layer 232. Advantages thereof include: achieving gradual change of energy bands, reducing interface electrical resistance, decreasing the operating voltage of the semiconductor light-emitting structure, and suppressing thermal inversion and mode hopping.

In a specific example, the number of layers of the plurality of fourth sub-transition layers in the fourth transition layer 274 is three, and conduction band energy levels of the three fourth sub-transition layer decrease layer-by-layer in a stacking arrangement direction from the second waveguide layer 240 to the second superlattice active layer 232. In other examples, there is no limitation on the number of layers of the fourth sub-transition layer.

In other examples, the fourth transition layer 274 is a single-layer structure, and the conduction band energy level of the fourth transition layer 274 is constant in the thickness direction thereof.

The function of the third transition layer 273 includes: reducing interfacial scattering of majority carriers, and enabling the majority carriers to be transported between the first superlattice active layer 231 and the first waveguide layer 220. A function of the fourth transition layer 274 includes: reducing the interfacial scattering of majority carriers, and enabling the majority carriers to be transported between the second superlattice active layer 232 and the second waveguide layer 240.

In the present embodiment, the active layer, the insertion layer, the second waveguide layer and the second limiting layer are located on a side of a portion of the first waveguide layer away from the first limiting layer. The semiconductor light-emitting structure further comprises: an insulating epitaxial layer, wherein the insulating epitaxial layer is located on portions of the first waveguide layer on both lateral sides of the active layer, the insertion layer, the second waveguide layer and the second limiting layer in a width direction, and a thermal conductivity of the insulating epitaxial layer is greater than that of the active layer.

In an example, the material of the insulating epitaxial layer comprises InP doped with Fe. The insulating epitaxial layer is not electrically conductive and carriers in the active layer 230 would not pass through the insulating epitaxial layer.

In an example, the semiconductor light-emitting structure further comprises: a contact layer disposed on a side of the second limiting layer away from the second waveguide layer. In one example, the contact layer is an InP contact layer, and is doped with conductive ions. The doping concentration of conductive ions in the contact layer is greater than that of conductive ions in the second limiting layer.

In an example, a thickness of the contact layer is 0.5 μm to 2 μm, such as 1 μm.

In an example, the doping concentration of conductive ions in the contact layer is 4×10¹⁸ atom/cm³˜2×10¹⁹ atom/cm³, such as 8×10¹⁸ atom/cm³.

In the present example, the semiconductor light-emitting structure further comprises: a front electrode disposed on a side of the second limiting layer 250 away from the semiconductor substrate layer 200, optionally, the front electrode is disposed on a side of the contact layer away from the second limiting layer 250; and a back electrode disposed on a side of the semiconductor substrate layer 200 away from the first limiting layer 210.

### Embodiment 2

The difference between the present embodiment and Embodiment 1 is that, referring to FIG. 3, the first superlattice active layer 231 comprises a first sub-superlattice region 231a and a second sub-superlattice region 231b, wherein the second sub-superlattice region 231b is disposed on a side of the first sub-superlattice region 231a away from the first waveguide layer 220, and a doping concentration of conductive ions in the second sub-superlattice region 231b is greater than that of conductive ions in the first sub-superlattice region 231a; and, the second superlattice active layer 232 comprises a third sub-superlattice region 232b and a fourth sub-superlattice region 232a, wherein the fourth sub-superlattice region 232a is disposed on a side of the third sub-superlattice region 232b away from the insertion layer 260, and a doping concentration of conductive ions in the third sub-superlattice region 232b is greater than that of conductive ions in the fourth sub-superlattice region 232a.

In other examples, the first superlattice active layer comprises a first sub-superlattice region and a second sub-superlattice region, wherein the second sub-superlattice region is disposed on a side of the first sub-superlattice region away from the first waveguide layer, and a doping concentration of conductive ions in the second sub-superlattice region is greater than that of conductive ions in the first sub-superlattice region; or, the second superlattice active layer comprises a third sub-superlattice region and a fourth sub-superlattice region, wherein the fourth sub-superlattice region is disposed on a side of the third sub-superlattice region away from the insertion layer, and a doping concentration of conductive ions in the third sub-superlattice region is greater than that of conductive ions in the fourth sub-superlattice region.

The doping concentration of conductive ions in the second sub-superlattice region 231b is greater than that of conductive ions in the first sub-superlattice region 231a, and a waveguide absorption loss of the second sub-superlattice region 231b for the light field is greater than that of the first sub-superlattice region 231a for the light field. A difference between the optical loss of the second sub-superlattice region 231b for the higher-order modes and the optical loss of the first sub-superlattice region 231a for the higher-order modes is greater than a difference between the optical loss of the second sub-superlattice region 231b for the basic mode and the optical loss of the first sub-superlattice region 231a for the basic mode, so that the higher-order modes are effectively suppressed, and the beam quality of the semiconductor light-emitting structure is improved.

The doping concentration of conductive ions in the third sub-superlattice region 232b is greater than that of conductive ions in the fourth sub-superlattice region 232a, and the waveguide absorption loss of the third sub-superlattice region 232b for the light field is greater than that of the fourth sub-superlattice region 232a for the light field. A difference between the optical loss of the third sub-superlattice region 232b for the higher-order modes and the optical loss of the fourth sub-superlattice region 232a for the higher-order modes is greater than a difference between the optical loss of the third sub-superlattice region 232b for the basic mode and the optical loss of the fourth sub-superlattice region 232a for the basic mode, so that the higher-order modes are effectively suppressed, and the beam quality of the semiconductor light-emitting structure is improved.

The third sub-superlattice region 232b and the second sub-superlattice region 231b are capable of generating a certain gain, which serves to reduce a threshold current density and improve a slope efficiency.

In an example, the doping concentration of conductive ions in the third sub-superlattice region 232b is 20% to 50% higher than that of conductive ions in the fourth sub-superlattice region 232a; and/or, the doping concentration of conductive ions in the second sub-superlattice region 231b is 20% to 50% higher than that of conductive ions in the first sub-superlattice region 231a. The significance of the above numerical range is that: if the doping concentration of conductive ions in the third sub-superlattice region 232b is too low, a degree of suppressing the higher-order modes by the third sub-superlattice region 232b is weakened, and if the doping concentration of conductive ions in the third sub-superlattice region 232b is too high, the overlap range of a current operating interval of the third sub-superlattice region 232b and that of the fourth sub-superlattice region 232a is relatively small. If the doping concentration of conductive ions in the second sub-superlattice region 231b is too low, a degree of suppressing the higher-order modes by the second sub-superlattice region 231b is weakened, and if the doping concentration of the conductive ions in the second sub-superlattice region 231b is too high, the overlap range of a current operating interval of the second sub-superlattice region 231b and that of the first sub-superlattice region 231a is relatively small.

With respect to contents in the present embodiment that are the same as in Embodiment 1, no further details will be described.

### Embodiment 3

The present embodiment provides a method for manufacturing the semiconductor light-emitting structure, comprising: providing a semiconductor substrate layer; forming a first limiting layer, a first waveguide layer, an active layer, a second waveguide layer, and a second limiting layer in sequence on the semiconductor substrate layer; wherein the step of forming the active layer comprises: stacking a first superlattice active layer and a second superlattice active layer in sequence; the method for manufacturing the semiconductor light-emitting structure further comprises: before forming the second superlattice active layer, forming an insertion layer on a side of the first superlattice active layer away from the first waveguide layer; wherein a refractive index of the insertion layer is less than an effective refractive index of the first superlattice active layer and less than an effective refractive index of the second superlattice active layer.

In an example, the method for manufacturing the semiconductor light-emitting structure further comprises: before forming the insertion layer, forming a first lattice matching layer on a side of the first superlattice active layer away from the first waveguide layer; and forming a first transition layer on a side of the first lattice matching layer away from the first waveguide layer; wherein a conduction band energy level of the first transition layer is higher than that of the first lattice matching layer and lower than that of the insertion layer; and the step of forming the insertion layer comprises: forming the insertion layer on a side of the first transition layer away from the first waveguide layer.

In an example, the step of forming the first transition layer on a side of the first lattice matching layer away from the first waveguide layer comprises forming a plurality of first sub-transition layers stacked in sequence; wherein conduction band energy levels of the plurality of first sub-transition layers stacked in sequence increase layer-by-layer in a stacking arrangement direction from the first superlattice active layer to the insertion layer.

In other examples, the first transition layer is a single-layer structure and the conduction band energy level of the first transition layer is constant in a thickness direction thereof.

In other examples, the first transition layer is not provided.

In an example, the method for manufacturing the semiconductor light-emitting structure further comprises: before forming the second superlattice active layer, forming a second transition layer on a side of the insertion layer away from the first superlattice active layer; forming a second lattice matching layer on a side of the second transition layer away from the first superlattice active layer; wherein a conduction band energy level of the second transition layer is higher than that of the second lattice matching layer and lower than that of the insertion layer; and the step of forming the second superlattice active layer comprises: forming the second superlattice active layer on a side of the second lattice matching layer away from the first superlattice active layer.

In an example, the step of forming the second transition layer on a side of the insertion layer away from the first superlattice active layer comprises: forming a plurality of second sub-transition layers stacked in sequence; wherein conduction band energy levels of the plurality of second sub-transition layers stacked in sequence increase layer-by-layer in a stacking arrangement direction from the second superlattice active layer to the insertion layer.

In other examples, the second transition layer is a single-layer structure and the conduction band energy level of the second transition layer is constant in a thickness direction thereof.

In other examples, the second transition layer is not provided.

In other examples, the first lattice matching layer and the second lattice matching layer are provided without providing the first transition layer and the second transition layer. In other examples, only one of the first lattice matching layer and the second lattice matching layer is provided. In other examples, none of the first lattice matching layer and the second lattice matching layer is provided. In other examples, only one of the first transition layer and the second transition layer is provided. In other examples, none of the first transition layer and the second transition layer is provided.

In an example, the method for manufacturing the semiconductor light-emitting structure further comprises: before forming the first superlattice active layer, forming a third transition layer on a side of the first waveguide layer away from the first limiting layer; and forming a third lattice matching layer on a side of the third transition layer away from the first limiting layer; wherein a conduction band energy level of the third transition layer is higher than that of the third lattice matching layer and lower than that of the first waveguide layer; and the step of forming the first superlattice active layer comprises: forming the first superlattice active layer on a side of the third lattice matching layer away from the first limiting layer.

In an example, the step of forming the third transition layer on a side of the first waveguide layer away from the first limiting layer comprises: forming a plurality of third sub-transition layers stacked in sequence; wherein conduction band energy levels of the plurality of third sub-transition layers stacked in sequence decrease layer-by-layer in a stacking arrangement direction from the first waveguide layer to the first superlattice active layer.

In other examples, the third transition layer is a single-layer structure and the conduction band energy level of the third transition layer is constant in a thickness direction thereof.

In other examples, the third transition layer is not provided.

In an example, the method for manufacturing the semiconductor light-emitting structure further comprises: before forming the second waveguide layer, forming a fourth lattice matching layer on a side of the second superlattice active layer away from the first superlattice active layer; and forming a fourth transition layer on a side of the fourth lattice matching layer away from the first superlattice active layer, wherein a conduction band energy level of the fourth transition layer is higher than that of the fourth lattice matching layer and lower than that of the second waveguide layer; and the step of forming the second waveguide layer comprises: forming the second waveguide layer on a side of the fourth transition layer away from the first superlattice active layer.

In an example, the step of forming the fourth transition layer on a side of the fourth lattice matching layer away from the first superlattice active layer comprises: forming a plurality of fourth sub-transition layers stacked in sequence; wherein conduction band energy levels of the plurality of fourth sub-transition layers stacked in sequence decrease layer-by-layer in a stacking arrangement direction from the second waveguide layer to the second superlattice active layer.

In other examples, the fourth transition layer is a single-layer structure and the conduction band energy level of the fourth transition layer is constant in a thickness direction thereof.

In other examples, the fourth transition layer is not provided.

In other examples, the third lattice matching layer and the fourth lattice matching layer are provided without providing the third transition layer and the fourth transition layer. In other examples, only one of the third lattice matching layer and the fourth lattice matching layer is provided. In other examples, none of the third lattice matching layer and the fourth lattice matching layer is provided. In other examples, only one of the third transition layer and the fourth transition layer is provided. In other examples, none of the third transition layer and the fourth transition layer is provided.

In an example, the step of forming the first superlattice active layer comprises: forming a first sub-superlattice region and a second sub-superlattice region stacked in sequence, wherein the second sub-superlattice region is disposed on a side of the first sub-superlattice region away from the first waveguide layer, and a doping concentration of conductive ions in the second sub-superlattice region is greater than that of conductive ions in the first sub-superlattice region; and/or, the step of forming the second superlattice active layer comprises: forming a third sub-superlattice region and a fourth sub-superlattice region stacked in sequence, wherein the fourth sub-superlattice region is disposed on a side of the third sub-superlattice region away from the insertion layer, and a doping concentration of conductive ions in the third sub-superlattice region is greater than that of conductive ions in the fourth sub-superlattice region.

In another example, the doping concentration of conductive ions in the first superlattice active layer is constant in the thickness direction thereof. The doping concentration of the conductive ions in the second superlattice active layer is constant in the thickness direction thereof.

In an example, the method further comprises: forming a mask layer on a side of a portion of the second limiting layer away from the second waveguide layer; etching the second limiting layer, the second waveguide layer, the active layer, and the insertion layer by using the mask layer as a mask, until the first waveguide layer is exposed; and thereafter, removing the mask layer. In a specific example, the second limiting layer, the second waveguide layer, the active layer, the insertion layer, and a partial thickness of the first waveguide layer are etched by using the mask layer as a mask.

In an example, if the first lattice matching layer and the first transition layer have been formed, during the process of etching the second limiting layer, the second waveguide layer, the active layer, and the insertion layer by using the mask layer as a mask, the first lattice matching layer and the first transition layer are also etched.

In an example, if the second lattice matching layer and the second transition layer have been formed, during the process of etching the second limiting layer, the second waveguide layer, the active layer, and the insertion layer by using the mask layer as a mask, the second lattice matching layer and the second transition layer are also etched.

In an example, if the third lattice matching layer and the third transition layer have been formed, during the process of etching the second limiting layer, the second waveguide layer, the active layer, and the insertion layer by using the mask layer as a mask, the third lattice matching layer and the third transition layer are also etched.

In an example, if the fourth lattice matching layer and a fourth transition layer have been formed, during the process of etching the second limiting layer, the second waveguide layer, the active layer and the insertion layer by using the mask layer as a mask, the fourth lattice matching layer and the fourth transition layer are also etched.

In an example, the method for manufacturing the semiconductor light-emitting structure further comprises: after etching the second limiting layer, the second waveguide layer, the active layer and the insertion layer by using the mask layer as a mask, forming an insulating epitaxial layer on portions of the first waveguide layer on both lateral sides of the active layer, the insertion layer, the second waveguide layer, and the second limiting layer in a width direction thereof, wherein a thermal conductivity of the insulating epitaxial layer is greater than that of the active layer; forming an anti-reflection film on a front cavity surface of the semiconductor light-emitting structure; and forming a reflection enhancement film on a back cavity surface of the semiconductor light-emitting structure.

Apparently, the above embodiments are merely examples for the sake of clarity, and are not intended to be a limitation to the implementing ways. To a person with ordinary skill in the art, other variations or changes in different forms may be made on the basis of the above description. It is neither necessary nor possible to exhaust all of the embodiments herein. Any obvious variation or change derived therefrom are still within the scope of protection of the present application.

1. A semiconductor light-emitting structure, wherein the semiconductor light-emitting structure comprises: a semiconductor substrate layer, a first limiting layer, a first waveguide layer, an active layer, a second waveguide layer, and a second limiting layer stacked in sequence; wherein the active layer comprises a first superlattice active layer and a second superlattice active layer stacked in sequence, and the second superlattice active layer is located on a side of the first superlattice active layer away from the first waveguide layer;
the semiconductor light-emitting structure further comprises: an insertion layer disposed between the second superlattice active layer and the first superlattice active layer, wherein a refractive index of the insertion layer is less than an effective refractive index of the first superlattice active layer and less than an effective refractive index of the second superlattice active layer;
a thickness of the insertion layer is 50% to 150% of a thickness of the first superlattice active layer, the thickness of the insertion layer is 50% to 150% of a thickness of the second superlattice active layer, and the thickness of the insertion layer is 15% to 50% of a light-emitting wavelength of the semiconductor light-emitting structure.

2. The semiconductor light-emitting structure according to claim 1, wherein the semiconductor light-emitting structure further comprises:
a first lattice matching layer disposed between the first superlattice active layer and the insertion layer, and a first transition layer disposed between the first lattice matching layer and the insertion layer, wherein the first lattice matching layer is in contact with the first superlattice active layer, a conduction band energy level of the first transition layer is higher than that of the first lattice matching layer and lower than that of the insertion layer;
and/or, the semiconductor light-emitting structure further comprises: a second lattice matching layer disposed between the second superlattice active layer and the insertion layer, and a second transition layer disposed between the second lattice matching layer and the insertion layer, wherein the second lattice matching layer is in contact with the second superlattice active layer, a conduction band energy level of the second transition layer is higher than that of the second lattice matching layer and lower than that of the insertion layer.

3. The semiconductor light-emitting structure according to claim 2, wherein the first transition layer comprises a plurality of first sub-transition layers stacked in sequence; conduction band energy levels of the plurality of first sub-transition layers stacked in sequence increase layer-by-layer in a stacking arrangement direction from the first superlattice active layer to the insertion layer; or, the first transition layer is a single-layer structure, and the conduction band energy level of the first transition layer is constant in a thickness direction thereof.

4. The semiconductor light-emitting structure according to claim 2, wherein the second transition layer comprises a plurality of second sub-transition layers stacked in sequence; conduction band energy levels of the plurality of second sub-transition layers stacked in sequence increase layer-by-layer in a stacking arrangement direction from the second superlattice active layer to the insertion layer; or, the second transition layer is a single-layer structure, and the conduction band energy level of the second transition layer is constant in a thickness direction thereof.

5. The semiconductor light-emitting structure according to claim 1, wherein the semiconductor light-emitting structure further comprises: a third lattice matching layer disposed between the first superlattice active layer and the first waveguide layer, and a third transition layer disposed between the third lattice matching layer and the first waveguide layer, wherein the third lattice matching layer is in contact with the first superlattice active layer, and a conduction band energy level of the third transition layer is higher than that of the third lattice matching layer and lower than that of the first waveguide layer;
and/or, the semiconductor light-emitting structure further comprises: a fourth lattice matching layer disposed between the second superlattice active layer and the second waveguide layer, and a fourth transition layer disposed between the fourth lattice matching layer and the second waveguide layer, wherein the fourth lattice matching layer is in contact with the second superlattice active layer, and a conduction band energy level of the fourth transition layer is higher than that of the fourth lattice matching layer and lower than that of the second waveguide layer.

6. The semiconductor light-emitting structure according to claim 5, wherein the third transition layer comprises a plurality of third sub-transition layers stacked in sequence; conduction band energy levels of the plurality of third sub-transition layers stacked in sequence decrease layer-by-layer in a stacking arrangement direction from the first waveguide layer to the first superlattice active layer; or, the third transition layer is a single-layer structure, and the conduction band energy level of the third transition layer is constant in a thickness direction thereof.

7. The semiconductor light-emitting structure according to claim 5, wherein the fourth transition layer comprises a plurality of fourth sub-transition layers stacked in sequence; conduction band energy levels of the plurality of fourth sub-transition layers stacked in sequence decrease layer-by-layer in a stacking arrangement direction from the second waveguide layer to the second superlattice active layer; or, the fourth transition layer is a single-layer structure, and the conduction band energy level of the fourth transition layer is constant in a thickness direction thereof.

8. The semiconductor light-emitting structure according to claim 1, wherein the insertion layer is an InP insertion layer with or without doped conductive ions, or the insertion layer is an InAlAs insertion layer with or without doped conductive ions, or the insertion layer is an InGaAlAs insertion layer with or without doped conductive ions.

9. (canceled)

10. The semiconductor light-emitting structure according to claim 1, wherein the first superlattice active layer comprises a plurality of first barrier layers and a plurality of first quantum well layers, the first barrier layers and the first quantum well layers are stacked in an alternating and spaced way with respect to each other, both a top layer and a bottom layer of the first superlattice active layer are one of the first barrier layers, and a conduction band energy level of each of the first quantum well layers is lower than that of each of the first barrier layers;
the second superlattice active layer comprises a plurality of second barrier layers and a plurality of second quantum well layers, the second barrier layers and the second quantum well layers are stacked in an alternating and spaced way with respect to each other, both a top layer and a bottom layer of the second superlattice active layer are one of the second barrier layers, and a conduction band energy level of each of the second quantum well layers is lower than that of each of the second barrier layers;
a conduction band energy level of the insertion layer is higher than that of each of the first quantum well layers and lower than that of each of the first barrier layers, and the conduction band energy level of the insertion layer is higher than that of each of the second quantum well layers and lower than that of each of the second barrier layers.

11. (canceled)

12. (canceled)

13. The semiconductor light-emitting structure according to claim 1, wherein the first superlattice active layer comprises a first sub-superlattice region and a second sub-superlattice region, wherein the second sub-superlattice region is disposed on a side of the first sub-superlattice region away from the first waveguide layer, and a doping concentration of conductive ions in the second sub-superlattice region is greater than that of conductive ions in the first sub-superlattice region; and/or, the second superlattice active layer comprises a third sub-superlattice region and a fourth sub-superlattice region, wherein the fourth sub-superlattice region is disposed on a side of the third sub-superlattice region away from the insertion layer, and a doping concentration of conductive ions in the third sub-superlattice region is greater than that of conductive ions in the fourth sub-superlattice region.

14. The semiconductor light-emitting structure according to claim 13, wherein the doping concentration of conductive ions in the third sub-superlattice region is 20% to 50% higher than that of conductive ions in the fourth sub-superlattice region; and/or, the doping concentration of conductive ions in the second sub-superlattice region is 20% to 50% higher than that of conductive ions in the first sub-superlattice region.

15. The semiconductor light-emitting structure according to claim 1, wherein an middle surface between a surface on a side of the first superlattice active layer away from the second superlattice active layer to a surface on a side of the second superlattice active layer away from the first superlattice active layer is located in the insertion layer; a distance from the middle surface to the surface on the side of the first superlattice active layer away from the second superlattice active layer is equal to a distance from the middle surface to the surface on the side of the second superlattice active layer away from the first superlattice active layer.

16. A method for manufacturing the semiconductor light-emitting structure according to claim 1, wherein the method comprises:
providing a semiconductor substrate layer;
forming a first limiting layer, a first waveguide layer, an active layer, a second waveguide layer, and a second limiting layer in sequence on the semiconductor substrate layer; wherein the step of forming the active layer comprises: stacking a first superlattice active layer and a second superlattice active layer in sequence;
the method for manufacturing the semiconductor light-emitting structure further comprises: before forming the second superlattice active layer, forming an insertion layer on a side of the first superlattice active layer away from the first waveguide layer; wherein a refractive index of the insertion layer is less than an effective refractive index of the first superlattice active layer and less than an effective refractive index of the second superlattice active layer.

17. The method according to claim 16 for manufacturing the semiconductor light-emitting structure, wherein the method further comprises: before forming the insertion layer, forming a first lattice matching layer on a side of the first superlattice active layer away from the first waveguide layer; and forming a first transition layer on a side of the first lattice matching layer away from the first waveguide layer; wherein a conduction band energy level of the first transition layer is higher than that of the first lattice matching layer and lower than that of the insertion layer; and the step of forming the insertion layer comprises: forming the insertion layer on a side of the first transition layer away from the first waveguide layer;
and/or, the method further comprises: before forming the second superlattice active layer, forming a second transition layer on a side of the insertion layer away from the first superlattice active layer; forming a second lattice matching layer on a side of the second transition layer away from the first superlattice active layer; wherein a conduction band energy level of the second transition layer is higher than that of the second lattice matching layer and lower than that of the insertion layer; and the step of forming the second superlattice active layer comprises: forming the second superlattice active layer on a side of the second lattice matching layer away from the first superlattice active layer.

18. The method according to claim 17 for manufacturing the semiconductor light-emitting structure, wherein the step of forming the first transition layer on a side of the first lattice matching layer away from the first waveguide layer comprises forming a plurality of first sub-transition layers stacked in sequence; wherein conduction band energy levels of the plurality of first sub-transition layers stacked in sequence increase layer-by-layer in a stacking arrangement direction from the first superlattice active layer to the insertion layer.

19. The method according to claim 17 for manufacturing the semiconductor light-emitting structure, wherein the step of forming the second transition layer on a side of the insertion layer away from the first superlattice active layer comprises: forming a plurality of second sub-transition layers stacked in sequence; wherein conduction band energy levels of the plurality of second sub-transition layers stacked in sequence increase layer-by-layer in a stacking arrangement direction from the second superlattice active layer to the insertion layer.

20. The method according to claim 16 for manufacturing the semiconductor light-emitting structure, wherein the method further comprises: before forming the first superlattice active layer, forming a third transition layer on a side of the first waveguide layer away from the first limiting layer; and forming a third lattice matching layer on a side of the third transition layer away from the first limiting layer; wherein a conduction band energy level of the third transition layer is higher than that of the third lattice matching layer and lower than that of the first waveguide layer; and the step of forming the first superlattice active layer comprises: forming the first superlattice active layer on a side of the third lattice matching layer away from the first limiting layer;
and/or, the method further comprises: before forming the second waveguide layer, forming a fourth lattice matching layer on a side of the second superlattice active layer away from the first superlattice active layer; and forming a fourth transition layer on a side of the fourth lattice matching layer away from the first superlattice active layer, wherein a conduction band energy level of the fourth transition layer is higher than that of the fourth lattice matching layer and lower than that of the second waveguide layer; and the step of forming the second waveguide layer comprises: forming the second waveguide layer on a side of the fourth transition layer away from the first superlattice active layer.

21. The method according to claim 20 for manufacturing the semiconductor light-emitting structure, wherein the step of forming the third transition layer on a side of the first waveguide layer away from the first limiting layer comprises: forming a plurality of third sub-transition layers stacked in sequence; wherein conduction band energy levels of the plurality of third sub-transition layers stacked in sequence decrease layer-by-layer in a stacking arrangement direction from the first waveguide layer to the first superlattice active layer.

22. The method according to claim 20 for manufacturing the semiconductor light-emitting structure, wherein the step of forming the fourth transition layer on a side of the fourth lattice matching layer away from the first superlattice active layer comprises: forming a plurality of fourth sub-transition layers stacked in sequence; wherein conduction band energy levels of the plurality of fourth sub-transition layers stacked in sequence decrease layer-by-layer in a stacking arrangement direction from the second waveguide layer to the second superlattice active layer.

23. The method according to claim 16 for manufacturing the semiconductor light-emitting structure, wherein the step of forming the first superlattice active layer comprises: forming a first sub-superlattice region and a second sub-superlattice region stacked in sequence, wherein the second sub-superlattice region is disposed on a side of the first sub-superlattice region away from the first waveguide layer, and a doping concentration of conductive ions in the second sub-superlattice region is greater than that of conductive ions in the first sub-superlattice region;
and/or, the step of forming the second superlattice active layer comprises: forming a third sub-superlattice region and a fourth sub-superlattice region stacked in sequence, wherein the fourth sub-superlattice region is disposed on a side of the third sub-superlattice region away from the insertion layer, and a doping concentration of conductive ions in the third sub-superlattice region is greater than that of conductive ions in the fourth sub-superlattice region.
